(19) United States
(12) Patent Application Publication
(10) Pub. No.: US 2004/0144986 A1
(43) Pub. Date: Jul. 29, 2004

(54) Light emitting diode having anti-reflection layer and method of making the same

(75) Inventors: Shi-Ming Chen, Tainan (TW); Wen-Liang Li, Tainan (TW)

Correspondence Address: LOWE HAUPTMAN GILMAN AND BERNER, LLP, 1700 DIAGONAL ROAD, SUITE 300 /310, ALEXANDRIA, VA, 22314, US

(73) Assignee: EPITECH CORPORATION, LTD.

(21) Appl. No.: 10/436,086

(22) Filed: May 13, 2003

(30) Foreign Application Priority Data
Jan. 23, 2003 (TW) 92101514

(51) Int. Cl. H01L 33/00

(52) U.S. Cl. 257/94

(57) ABSTRACT

A light emitting diode (LED) having an anti-reflection layer and a method of making the same are disclosed. The present invention is featured in forming an anti-reflection layer on a window layer of the LED, thereby reducing the chance of the photons generated by the LED to be totally reflected at the interface between the window layer and air. The process used for forming the anti-reflection layer can be such as plasma enhanced chemical vapor deposition (PECVD), sputtering, thermal evaporation or electron-beam evaporation, etc. Furthermore, the refractive index of the aforementioned anti-reflection layer is between 3 and 1.5, and the material forming the anti-reflection layer can be such as Si₃N₄ or ZnSe, etc.

### FIELD OF THE INVENTION

The present invention relates to the structure of a light-emitting diode (LED) and a method of making the same, and more particularly, to a LED having an anti-reflection layer and the manufacturing method thereof.

### BACKGROUND OF THE INVENTION

The device structure of a conventional AlGaInP LED is such as shown in FIG. 1, and the structure shown in FIG. 1 can be fabricated according to the process described as follows. At first, an upper epitaxial buffer layer 20 (made of a n-typed GaAs material), a confining layer 30 (made of n-typed AlGaInP material with a wide energy gap), an active layer 40 (made of AlGaInP material with a narrow energy gap or multi-quantum wells (MQWs)), a confining layer 50 (made of a p-typed AlGaInP material with a wide energy gap), and a window layer 60 (made of a p-typed GaP material) are sequentially formed on a substrate 100 (made of a n-typed GaAs material). Thereafter, a p-typed ohmic metal electrode 70 and a n-typed ohmic metal electrode 80 are respectively deposited on one portion of the window layer 60 and the lower surface of the substrate 10.

In the conventional LEDs mainly utilizing the AlGaInP-related material as described above, GaP is frequently used as the material forming the window layer 60. However, since the refractive index of GaP is about 3 and has a large difference from the refractive index of air, most of the photons generated in the active layer 40 will be totally reflected from the interface between the window layer 60 and air before a LED is packaged, thus causing the photons to be absorbed by the LED. Further, although the aforementioned LED is commonly packaged by using an epoxy resin material, yet the refractive index of the epoxy resin material is about 1.5 and still has large difference from the refractive index of the GaP material forming the window layer 60. Therefore, there is a need for overcoming the aforementioned disadvantage.

### SUMMARY OF THE INVENTION

In view of the aforementioned disadvantage of the conventional AlGaInP LED, one object of the present invention is to provide a LED having an anti-reflection layer and a method for making the same, thereby reducing the chance of the photons generated by the LED to be totally reflected from the interface between the window layer and air.

The other object of the present invention is to provide a LED having an anti-reflection layer and a method for making the same, wherein for the chips not using the epoxy packaging method, the light reflected on the surface of LED can be reduced via the addition of the anti-reflection layer.

According to the aforementioned objects, the present invention provides a LED having an anti-reflection layer, the LED comprising: a first ohmic metal electrode having a first electrical property; a substrate located on the first ohmic metal electrode having the first electrical property; a semiconductor epitaxial structure located on the substrate; a window layer located on the semiconductor epitaxial structure; a second ohmic metal electrode having a second electrical property, located on one portion of the window layer; and an anti-reflection layer at least located on the other portion of the window layer, wherein the refractive index of the aforementioned anti-reflection layer is between 1.5 and 3, and the material forming the anti-reflection layer can be such as Si₃N₄, ZnSe or any other material.

According to the aforementioned objects, the present invention provides a method for making a LED having an anti-reflection layer, the method comprising the steps of: first providing a substrate; then forming a semiconductor epitaxial structure on the substrate; then forming a window layer on the semiconductor epitaxial structure; then respectively forming a first ohmic metal electrode having a first electrical property and a second ohmic metal electrode having a second electrical property on a lower surface of the substrate and one portion of the window layer; thereafter forming an anti-reflection layer, wherein the anti-reflection layer is at least located on the other portion of the window layer. Further, in the manufacturing method of the present invention, the aforementioned anti-reflection layer can be formed by such as a plasma enhanced chemical vapor deposition (PECVD), sputtering, thermal evaporation, or electron-beaming evaporation, etc. Moreover, the refractive index of the aforementioned anti-reflection layer is between 1.5 and 3, and the material forming the anti-reflection layer can be such as Si₃N₄, ZnSe or other material.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

The foregoing aspects and many of the attendant advantages of this invention will become more readily appreciated as the same becomes better understood by reference to the following detailed description, when taken in conjunction with the accompanying drawings, wherein:

FIG. 1 is a cross-sectional view showing the structure of a conventional AlGaInP LED;

FIG. 2 is a cross-sectional view showing the structure of a LED having an anti-reflection layer, according to a preferred embodiment of the present invention;

FIG. 3 is a diagram showing the relationship between transmittance and wavelength obtained by varying the thickness of the Si₃N₄ anti-reflection layer while the thickness of the p-typed GaP window layer is 8 μm;

FIG. 4 is a diagram showing the relationship between transmittance and wavelength obtained by varying the thickness of the p-typed GaP window layer and fixing the thickness of the Si₃N₄ anti-reflection layer to ¼ of the wavelength;

FIG. 5 is a diagram showing the relationship between transmittance and wavelength obtained by varying the material forming the anti-reflection layer while the thickness of the p-typed GaP window layer is 8 μm; and

FIG. 6 is a diagram showing the comparative relationship between electric current injected and luminance intensity for a LED having an anti-reflection layer according to the present invention.

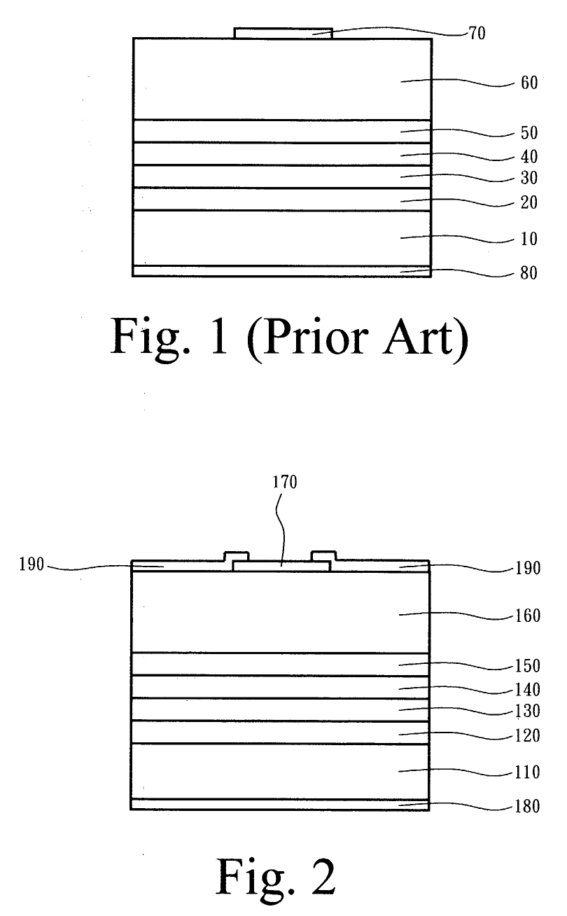

### DETAILED DESCRIPTION OF THE PREFERRED EMBODIMENT

The present invention relates to the structure of a LED having an anti-reflection layer and a method for making the same. As long as LEDs are featured in respectively forming the positive and negative electrodes on different sides of the substrate, then the LEDs are included in the application scope of the present invention, and the present invention is not limited to the LEDs mainly utilizing the AlGaInP-related material.

Referring to FIG. 2, FIG. 2 is a cross-sectional view showing the structure of a LED having an anti-reflection layer, according to a preferred embodiment of the present invention. The structure shown in FIG. 2 can be fabricated according to the process described as follows. At first, a substrate 110 is provided, and the substrate 110 can be made of a GaAs material having a first electrical property. Thereafter, a buffer layer 120 is formed on the substrate 110, wherein the material forming the buffer layer 120 can be such as the GaAs material having the first electrical property. Then, a confining layer 130 having the first electrical property is formed on the buffer layer 120, and the material forming the confining layer 130 can be such as an AlGaInP material having the first electrical property with a wide energy gap. Thereafter, an active layer 140 is formed on the confining layer 130 having the first electrical property, and the material forming the active layer 140 can be such as an AlGaInP material with a narrow energy gap or multi-quantum wells. Then, a confining layer 150 having a second electrical property is formed on the active layer 140, and the material forming the confining layer 150 can be such as an AlGaInP material having a second electrical property with a wide energy gap. Thereafter, a window layer 160 is formed on the confining layer 150 having the second electrical property, and the material forming the window layer 160 can be such a GaP material having the second electrical property. Then, an ohmic metal electrode 180 having the first electrical property and an ohmic metal electrode 170 having the second electrical property are respectively deposited on the lower surface of the substrate 110 and one portion of the window layer 160.

Thereafter, an anti-reflection layer 190 is formed to cover the other portion of the window layer 160. Further, the anti-reflection layer 190 also can cover one portion of the ohmic metal electrode 170 having the second electrical property, such as shown in FIG. 2. Moreover, the aforementioned anti-reflection layer 190 can be formed by such as y such as a plasma enhanced chemical vapor deposition, sputtering, thermal evaporation, or electron-beaming evaporation, etc.; the refractive index of the aforementioned anti-reflection layer is between 1.5 and 3; and the material forming the anti-reflection layer can be such as Si₃N₄ (whose refractive index is about 2), ZnSe or other material. Since Si₃N₄ and ZnSe both have good thermal conductivities, the tolerable electric current value injected thereto can be increased, wherein, when the wavelength is 413.3 nm, the refractive index of Si₃N₄ is 2.066, and the thermal conductivity is 15 Wm⁻¹K⁻¹. It is worthy to be noted that the first electrical property mentioned above can be either a positive type or a negative type, and the second electrical property is opposite to the first electrical property.

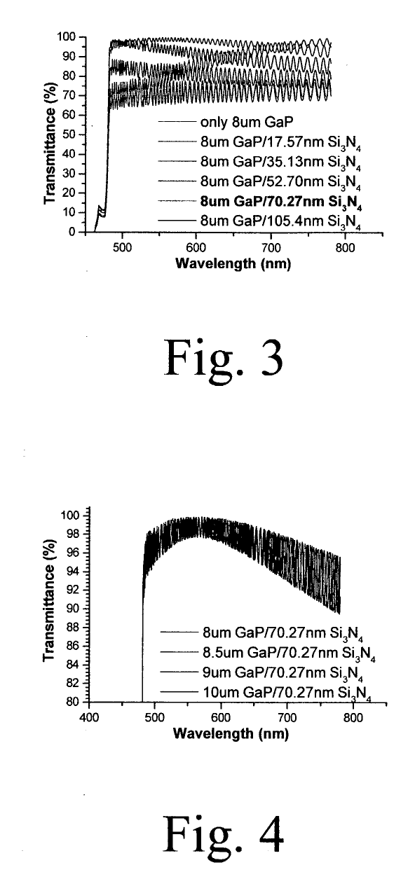

Referring to FIG. 3, FIG. 3 is a diagram showing the relationship between transmittance and wavelength obtained by varying the thickness of the Si₃N₄ anti-reflection layer while the thickness of the p-typed GaP window layer is 8 μm, wherein the horizontal axis therein stands for wavelength, and the vertical axis therein stands for transmittance. When the p-typed GaP window layer is 8 μm in thickness and the thickness of the Si₃N₄ anti-reflection layer is changed to various values, it can be known from FIG. 3, after theoretical computation (570 nm wavelength), that the transmittance is maximum when the thickness of the Si₃N₄ anti-reflection layer equals to ¼ of the wavelength, which is called quarter wave of optical thickness (QWOT), i.e. 70.27 nm.

Referring to FIG. 4, FIG. 4 is a diagram showing the relationship between transmittance and wavelength obtained by varying the thickness of the p-typed GaP window layer and fixing the thickness of the Si₃N₄ anti-reflection layer to ¼ of the wavelength, wherein the horizontal axis therein stands for wavelength, and the vertical axis therein stands for transmittance. When the thickness of the Si₃N₄ anti-reflection layer to ¼ of the wavelength, i.e. 70.27 nm, and the thickness of the p-typed GaP window layer is changed to 8 μm, 8.5 μm, 9 μm and 10 μm respectively, it can be known from FIG. 4, after theoretical computation (570 mm wavelength), that the transmittance is affected by the change of the thickness of the p-typed GaP window layer.

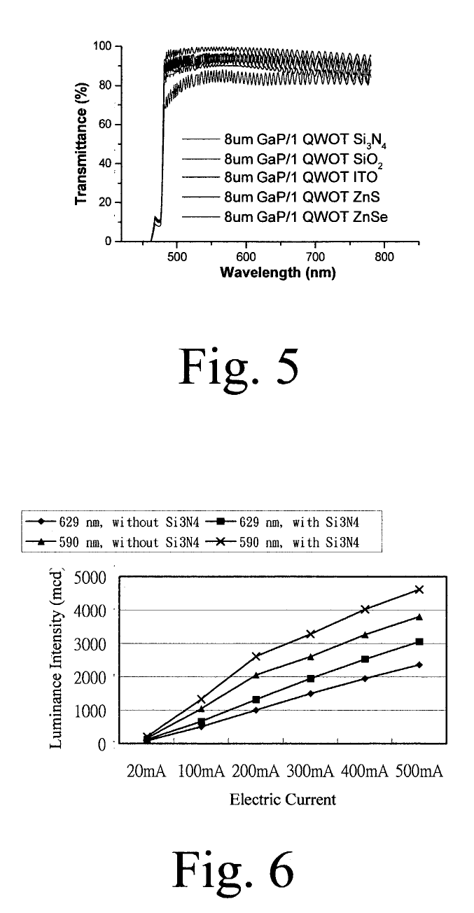

Referring to FIG. 5, FIG. 5 is a diagram showing the relationship between transmittance and wavelength obtained by varying the material forming the anti-reflection layer while the thickness of the p-typed GaP window layer is 8 μm, wherein the horizontal axis therein stands for wavelength, and the vertical axis therein stands for transmittance. When the thickness of the p-typed GaP window layer is 8 μm, and the material forming the anti-reflection layer is changed to Si₃N₄, SiO₂, ITO, ZnS and ZnSe respectively, it can be known from FIG. 5, after theoretical computation (570 nm wavelength), that the anti-reflection layer mad of Si₃N₄ has the biggest transmittance value while the thickness of the anti-reflection layer is ¼ of the wavelength.

Referring to FIG. 6, FIG. 6 is a diagram showing the comparative relationship between electric current injected and luminance intensity for a LED having an anti-reflection layer according to the present invention, wherein the horizontal axis therein stands for electric current injected to the LED, and the vertical axis therein stands for luminance intensity. FIG. 6 shows the comparison the light output between the conventional LED and the LED having the Si₃N₄ anti-reflection layer, wherein the chip size used is 40 mil×40 mil, and the thickness of the Si₃N₄ anti-reflection layer is ¼ of the wavelength. Such as shown in FIG. 6, with increasing the injected electric current to 500 mA, comparing to the conventional LED (without the Si₃N₄ anti-reflection layer) having the luminance wavelength of 629 nm, the LED of the present invention, having the Si₃N₄ anti-reflection layer and also the luminance wavelength of 629 nm, has 29.46% more light output. Similarly, with increasing the injected electric current to 500 mA, comparing to the conventional LED (without the Si₃N₄ anti-reflection layer) having the luminance wavelength of 590 nm, the LED of the present invention, having the Si₃N₄ anti-reflection layer and also the luminance wavelength of 590 nm, has 21.23% more light output.

To sum up, the overall transmittance of the window layer and anti-reflection layer can be greatly promoted by forming the anti-refection layer made of such as Si₃N₄ on the window of a LED, thereby increasing the luminance intensity of the LED. Hence, one advantage of the present invention is to provide a LED having an anti-reflection layer and a method for making the same, so that the chance of the photons generated by the LED to be totally reflected from the interface between the window layer and air is greatly reduced.

The other advantage of the present invention is to provide a LED having an anti-reflection layer and a method for making the same, so that for the chips not using the epoxy packaging method, the light reflected on the surface of LED is reduced via the addition of the anti-reflection layer.

As is understood by a person skilled in the art, the foregoing preferred embodiments of the present invention are illustrated of the present invention rather than limiting of the present invention. It is intended to cover various modifications and similar arrangements included within the spirit and scope of the appended claims, the scope of which should be accorded the broadest interpretation so as to encompass all such modifications and similar structures.

What is claimed is:

1. A light-emitting diode (LED) having an anti-reflection layer, said LED comprising:
a first ohmic metal electrode having a first electrical property;
a substrate located on said first ohmic metal electrode having said first electrical property;
a semiconductor epitaxial structure located on said substrate;
a window layer located on said semiconductor epitaxial structure;
a second ohmic metal electrode having a second electrical property, located on one portion of said window layer; and
an anti-reflection layer at least located on the other portion of said window layer.

2. The LED having the anti-reflection layer according to claim 1, wherein the material forming said substrate is a GaAs material having said first electrical property.

3. The LED having the anti-reflection layer according to claim 1, wherein said semiconductor epitaxial structure is a stacked structure comprising a first confining layer having said first electrical property, an active layer and a second confining layer having said second electrical property.

4. The LED having the anti-reflection layer according to claim 3, wherein the material forming said first confining layer having said first electrical property, said active layer and a second confining layer having said second electrical property is AlGaInP.

5. The LED having the anti-reflection layer according to claim 1, wherein the material forming said window layer is a GaP material having said second electrical property.

6. The LED having the anti-reflection layer according to claim 1, wherein there is a buffer layer included between said substrate and said semiconductor epitaxial structure.

7. The LED having the anti-reflection layer according to claim 6, wherein the material forming said buffer layer is a GaAs material having said first electrical property.

8. The LED having the anti-reflection layer according to claim 1, wherein the refractive index of said anti-reflection layer is between 1.5 and 3.

9. The LED having the anti-reflection layer according to claim 8, wherein the material forming said anti-reflection layer is Si₃N₄ or ZnSe.

10. A method for making a LED having an anti-reflection layer, said method comprising:
providing a substrate;
forming a semiconductor epitaxial structure on said substrate;
forming a window layer on said semiconductor epitaxial structure;
respectively forming a first ohmic metal electrode having a first electrical property and a second ohmic metal electrode having a second electrical property on a lower surface of said substrate and one portion of said window layer; and
forming an anti-reflection layer, wherein said anti-reflection layer is at least located on the other portion of said window layer.

11. The method for making the LED having the anti-reflection layer according to claim 10, wherein the material forming said substrate is a GaAs material having said first electrical property.

12. The method for making the LED having the anti-reflection layer according to claim 10, wherein said semiconductor epitaxial structure is a stacked structure comprising a first confining layer having said first electrical property, an active layer and a second confining layer having said second electrical property.

13. The method for making the LED having the anti-reflection layer according to claim 10, wherein the material forming said first confining layer having said first electrical property, said active layer and a second confining layer having said second electrical property is AlGaInP.

14. The method for making the LED having the anti-reflection layer according to claim 10, wherein the material forming said window layer is a GaP material having said second electrical property.

15. The method for making the LED having the anti-reflection layer according to claim 10, wherein there is a buffer layer included between said substrate and said semiconductor epitaxial structure.

16. The method for making the LED having the anti-reflection layer according to claim 15 wherein the material forming said buffer layer is a GaAs material having said first electrical property.

17. The method for making the LED having the anti-reflection layer according to claim 10, said anti-reflection layer is formed by a plasma enhanced chemical vapor deposition (PECVD), sputtering, thermal evaporation, or electron-beaming evaporation.

18. The method for making the LED having the anti-reflection layer according to claim 10, wherein the refractive index of said anti-reflection layer is between 1.5 and 3.

19. The method for making the LED having the anti-reflection layer according to claim 18, wherein the material forming said anti-reflection layer is Si₃N₄ or ZnSe.
